(19) United States
(12) Patent Application Publication
(10) Pub. No.: US 2006/0126865 A1
(43) Pub. Date: Jun. 15, 2006

(54) Method and apparatus for adaptive sound processing parameters

(76) Inventors: Peter John Blamey, South Yarra (AU); Bonar Dickson, Abbotsford (AU); Brenton Robert Steele, Blackburn South (AU); Margaret Jane Steinberg, Port Melbourne (AU)

Correspondence Address: CHRISTIE, PARKER & HALE, LLP, PO BOX 7068, PASADENA, CA, 91109-7068, US

(21) Appl. No.: 11/011,493

(22) Filed: Dec. 13, 2004

(51) Int. Cl. H03G 7/00; H03G 9/00

(52) U.S. Cl. 381/102; 381/56; 381/106

(57) ABSTRACT

An input sound signal (210) is processed in order to meet a target dynamic range (910, 920). At least one gain, specific to the input sound signal (210), is applied to the input sound signal (210) to produce a processed sound signal (214). A dynamic range of the processed sound signal is measured, and a match of the measured dynamic range with the target dynamic range (910, 920) is determined. The gain is adjusted in accordance with at least one input sound signal-specific parameter, to improve the match of dynamic range of the processed sound signal (214) to the target dynamic range (910, 920). The input sound signal-specific parameter is adaptive in response to at least one monitored signal condition.

### FIELD OF THE INVENTION

The present invention relates to processing a sound signal in order to adjust characteristics of the sound signal to meet respective target levels. Such sound signal processing is of application in hearing aid sound signal processing, telecommunications sound signal processing, and the like.

### BACKGROUND TO THE INVENTION

Processing of sound for audio applications usually requires the sound signal to be amplified or adjusted to fall within a target dynamic range across the audio band, generally considered to be 20 Hz-20 kHz or a sub-range thereof. The target dynamic range is typically determined by the next stage of processing or, where the signal is to be optimised for a listener, by the intensity range that is both audible and comfortable at each frequency to a human listener.

In the case of a sound transmission system such as a telephone or a sound recording system, the target dynamic range will be the operating dynamic range of the transmission line or storage medium. Some or all of the frequency components of the sound signal being processed may fall outside of the target dynamic range, or there may be a mismatch between the dynamic range of the signal and the target dynamic range.

In the case of a human listener, there is usually an additional requirement that the target dynamic range must be matched or set in a controlled manner across the audible frequency band to produce matched loudness or a prescribed frequency response for the system as a whole. Such a prescribed frequency response generally aims to maximise the intelligibility of speech sounds without compromising the comfort of the listener or the quality of the sound. For musical sounds the target dynamic range and/or frequency response may be chosen to achieve a particular tone or balance of high and low pitch sounds, according to the preference of the listener.

Further, for each human listener, the target dynamic range may vary considerably across frequency, and may be narrow in extent between a minimum audible threshold and a maximum comfort threshold, particularly for a listener with impaired hearing. Similarly, the useable or optimal dynamic range for a listener with normal hearing may vary considerably across frequency and may be narrow in extent when there is ambient noise that masks the lower part of the listener's dynamic range.

A simple approach to address such problems is the use of a linear amplifier/attenuator designed to maximise the overlap of the dynamic range of the sound signal with the target dynamic range. A further refinement is to provide a sound processor that provides differing amounts of gain at different frequencies to optimise the match of the output signal to the target dynamic range in each frequency band. A subsequent processing stage may truncate the output dynamic range, for example at an upper end by saturation of an input mechanism, and at a lower end by thresholding or resolution limitations. However, where the signal is for delivery to a human listener, a lack of any truncation of the upper end of the output dynamic range may result in discomfort, trauma, or damage to the auditory system. For these and other reasons, a maximum power output level or other type of limiting mechanism is usually applied to the output of a linear sound processing system.

A more complex solution to the problems described above involves use of a compression scheme. Compression usually applies more gain to softer sounds and less gain to louder sounds such that the output dynamic range is less than or “compressed” relative to the input dynamic range. Thus, compression is a non-linear signal processing scheme. The ratio of the input dynamic range to the output dynamic range is known as the compression ratio. Compression parameters are often described in terms of a fixed input/output function at each frequency, as illustrated by the input/output functions 110, 120, 130 of FIG. 1. Each input/output function specifies, for a given input signal level, an output level to be produced by the sound processor.

The compression ratio is the inverse of the slope of the input/output function. As shown in FIG. 1, input/output function 130 has a slope of less than 1 and thus is a simple compression scheme. Input/output function 110 has a slope which is different at different portions of the input/output function, but is nevertheless said to provide compression. A linear amplifier does not cause compression and thus has an input/output function 120 with a slope of 1.

Among the most sophisticated signal processing techniques addressing such issues is the adaptive dynamic range optimisation (ADRO) technique set out in U.S. Pat. No. 6,731,767, the content of which is incorporated herein by reference. Rather than to focus on prescriptive gain or gain compression profiles, the approach adopted by the ADRO technique is to define a target dynamic range which is desired for the output sound signal, and to adjust a gain applied to an input signal in order to maintain a close match of the actual output dynamic range to the target dynamic range. The output level of the ADRO signal processor is thus constrained by a set of processing rules defined by fixed parameters. While the processing rules are satisfied, the signal processor operates as a linear amplifier. Should the processing rules not be satisfied, the gain applied by the processor is adaptively altered until the processing rules are satisfied.

For each frequency band, the ADRO signal processor determines the accuracy of the match of the output dynamic range to the target dynamic range, by taking a statistical measure of percentile estimators. A 30^{th} percentile estimator provides a measurement of a level below which the output signal remains for 30% of the measurement period. Where the signal is being processed for a human listener, the lower end of the target dynamic range is predefined by determining an audibility threshold of the listener. Should the 30^{th} percentile estimator be below the audibility threshold, the gain is increased slowly. A 90^{th} percentile estimator provides a measurement of a level below which the output signal remains for 90% of the measurement period. Again, where the signal is being processed for a human listener, the upper end of the target dynamic range is predefined by determining a boundary comfort level of the listener. Should the 90^{th} percentile estimator be above the boundary comfort level, the gain is decreased slowly. The 30^{th} and 90^{th} percentile estimators are thus of use in determining how well the output dynamic range matches the target dynamic range.

Two further rules are imposed in each frequency band when ADRO is applied for a human listener. The maximum output rule compares the magnitude of the output signal with a fixed maximum output limit. If the magnitude of the output signal is greater than the fixed maximum output limit, the magnitude is capped to the maximum output limit. The maximum gain rule compares the gain with a fixed maximum gain limit, and prevents the gain from exceeding the fixed maximum gain limit.

The ADRO processing scheme has been shown to provide improved audibility of soft sounds, improved intelligibility of speech both in quiet and in noise, and increased comfort and listener preferences relative to linear amplification and compression schemes. The ADRO processing scheme adapts the gain of the amplifier independently in each frequency band to provide optimum listening conditions based on the fixed parameters.

Any discussion of documents, acts, materials, devices, articles or the like which has been included in the present specification is solely for the purpose of providing a context for the present invention. It is not to be taken as an admission that any or all of these matters form part of the prior art base or were common general knowledge in the field relevant to the present invention as it existed before the priority date of each claim of this application.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### SUMMARY OF THE INVENTION

According to a first aspect, the present invention provides a method of processing at least one input sound signal to meet a target dynamic range, the method comprising:

applying at least one input sound signal-specific gain to the at least one input sound signal to produce a processed sound signal;

measuring a dynamic range of the processed sound signal;

determining a match of the measured dynamic range with the target dynamic range; and

adjusting each input sound signal-specific gain in accordance with at least one input sound signal-specific parameter to improve the match of dynamic range of the processed sound signal to the target dynamic range, wherein the at least one input sound signal-specific parameter is adaptive in response to at least one monitored signal condition.

According to a second aspect, the present invention provides a device for processing at least one input sound signal to meet a target dynamic range, the device comprising:

a gain stage for applying at least one input sound signal-specific gain to the at least one input sound signal to produce a processed sound signal;

an analyser for measuring a dynamic range of the processed sound signal and for determining a match of the measured dynamic range with the target dynamic range; and

a gain controller for adjusting each input sound signal-specific gain in accordance with at least one input sound signal-specific parameter to improve the match of dynamic range of the processed sound signal to the target dynamic range, wherein the at least one input sound signal-specific parameter is adaptive in response to at least one monitored signal condition.

According to a third aspect, the present invention provides a computer program for processing at least one input sound signal to meet a target dynamic range, the computer program comprising:

code for applying at least one input sound signal-specific gain to the at least one input sound signal to produce a processed sound signal;

code for measuring a dynamic range of the processed sound signal;

code for determining a match of the measured dynamic range with the target dynamic range; and

code for adjusting each input sound signal-specific gain in accordance with at least one input sound signal-specific parameter to improve the match of dynamic range of the processed sound signal to the target dynamic range, wherein the at least one input sound signal-specific parameter is adaptive in response to at least one monitored signal condition.

According to a fourth aspect, the present invention provides a computer program element comprising computer program code means to make a computer execute a procedure for processing at least one input sound signal to meet a target dynamic range, the computer program element comprising:

computer program code means for applying at least one input sound signal-specific gain to the at least one input sound signal to produce a processed sound signal;

computer program code means for measuring a dynamic range of the processed sound signal;

computer program code means for determining a match of the measured dynamic range with the target dynamic range; and

computer program code means for adjusting each input sound signal-specific gain in accordance with at least one input sound signal-specific parameter to improve the match of dynamic range of the processed sound signal to the target dynamic range, wherein the at least one input sound signal-specific parameter is adaptive in response to at least one monitored signal condition.

The at least one input sound signal may comprise a single sound signal such as a sound signal obtained from a microphone or a sound signal obtained from a transmission medium. Alternatively, the input sound signal may comprise a transformation of a single sound signal.

Alternatively, the input sound signal may comprise a portion of a sound signal and/or may comprise a transformation of a portion of a sound signal. In such embodiments, a plurality of input sound signals may be processed in accordance with the present invention, each input sound signal corresponding to a unique portion of a single sound signal.

The at least one input sound signal may comprise a portion of a sound signal obtained by frequency domain filtering, such that the at least one input sound signal comprises only those frequency components of the sound signal falling within a constrained frequency band. A plurality of such input sound signals, having a one-to-one correspondence with a plurality of frequency bands, may be processed in accordance with the present invention.

Additionally or alternatively the at least one input sound signal may comprise a portion of a sound signal obtained by a frequency transform approximation, such as a sine wave basis function transform. Additionally or alternatively the at least one input sound signal may comprise a portion of a sound signal obtained by time domain processing. Additionally or alternatively the at least one input sound signal may comprise a portion of a sound signal obtained by use of wavelet functions.

One input sound signal-specific gain may be applied to the or each input sound signal. Alternatively, a plurality of input sound signal-specific gains may be applied to the or each input sound signal.

In some embodiments of the invention, the monitored signal condition may comprise a measurement of a mismatch between the measured dynamic range and the target dynamic range. In such embodiments, the at least one input sound signal-specific parameter preferably comprises a gain slew rate of the gain adjustment, and such embodiments may further comprise controlling the gain slew rate to be larger when the mismatch is larger, and controlling the gain slew rate to be smaller when the mismatch is smaller. Such embodiments may be of use in providing a speedy settle time of the input sound signal-specific gain in response to a mismatch between the output dynamic range and the target dynamic range, even where the mismatch is large. Such embodiments may thus provide both for speedy suppression of overly loud audio signals such as an alarm, and for more measured gain refinements in the absence of a large mismatch.

In embodiments where the at least one input sound signal-specific parameter comprises gain slew rate, the gain slew rate for an increase in gain may be controlled to be different to the slew rate for a decrease in gain. For example, the gain slew rate for a reduction in gain may be permitted to be large, while the gain slew rate for an increase in gain may be limited to a moderate gain slew rate. Such embodiments may provide for swift suppression of audio shock signals such as facsimile tones or alarms, while providing for restrained gain increases, for example to avoid overly hasty gain increases during quiet signal periods.

In some embodiments of the invention, the at least one monitored signal condition may comprise an ambient noise signal condition. The ambient noise signal condition may be monitored from the same signal as is to be processed by the sound processor. Additionally or alternatively, the ambient noise signal condition may be monitored from at least one other signal, obtained from at least one microphone in the environment of a listener of the processed sound signal. In such embodiments, the at least one input sound signal-specific parameter may comprise one, and preferably comprises both, of a target audibility level and a target comfort level.

In some embodiments of the invention, the monitored signal condition may comprise monitoring for the presence of audio shock, in order to detect facsimile tones, alarms, loud speech and/or other types of audio shock. In such embodiments, the at least one input sound signal-specific parameter may comprise gain slew rate, wherein a large gain reduction slew rate is imposed for gain reduction in response to detection of presence of an audio shock. In such embodiments, the at least one input sound signal-specific parameter may additionally comprise a maximum output limit, wherein the maximum output limit is reduced in response to detection of presence of an audio shock.

In further embodiments of the invention, the gain may be prevented from increasing during periods in which no signal-of-interest is present. Such embodiments of the invention preferably further comprise monitoring an input signal in order to determine periods in which a signal-of-interest is present, and periods in which no signal-of-interest is present.

In embodiments of the invention in which the at least one monitored signal condition comprises ambient noise, the target dynamic range of the at least one input sound signal may be adaptive in response to the ambient noise. In such embodiments, a lower end of the target dynamic range may be increased in response to an increase in ambient noise level, in order to maintain the target dynamic range above the ambient noise level. Additionally or alternatively, in such embodiments an upper end of the target dynamic range may be increased in response to an increase in ambient noise, by an amount corresponding to an increase in listener's comfort level with ambient noise. Such embodiments are advantageous in providing a signal processing scheme whereby the target dynamic range is adaptive to allow for changes in ambient noise level. Further, such embodiments recognise that a listener's comfort level is often higher in the presence of greater ambient noise than in the presence of lesser ambient noise, and thus adapt the target dynamic range accordingly.

Further, in embodiments of the invention in which the at least one monitored signal condition comprises ambient noise, the target dynamic range of at least one high frequency band is preferably raised more than the target dynamic range of at least one low frequency band. Such embodiments recognise that low frequency noise impacts the intelligibility of high frequency components of the signal, that telephone speakers typically have greater high frequency capabilities, that speech typically shifts towards higher frequencies with increasing volume, and recognises the high frequency character of Hoth noise.

In embodiments of the invention, one or more of the following parameters relating to one or more input sound signals may be adaptive in response to the at least one monitored signal condition: maximum output limit(s), comfort target(s), audibility target(s), background noise target(s), maximum gain(s), minimum gain(s), increasing gain slew rate(s), decreasing gain slew rate(s), increasing percentile estimate slew rate(s) and decreasing percentile estimate slew rate(s).

In some embodiments of the invention, a plurality of input sound signals may be processed. In such embodiments, the at least one input sound signal-specific parameter of a first input sound signal may differ from the at least one input sound signal-specific parameter of a second input sound signal. For example where the present invention is implemented in a telephone system with a send signal and receive signal, the input sound signal-specific parameters of the receive signal may be controlled in response to ambient noise in the send signal. Where the present invention is implemented in a stereo listening device or a pair of hearing aids, the at least one input sound signal-specific parameter may be controlled in response to monitored conditions of two signals.

In preferred embodiments of the invention, a plurality of frequency bands of the sound signal are each processed in accordance with the method of the present invention. In such embodiments, the sound signal is preferably earlier divided by a filter bank into a plurality of frequency bands for separate processing. Alternatively, the present invention may be applied in a single frequency band of the sound signal, for example in embodiments where the sound signal is processed as a single band signal, or in embodiments where only one of a plurality of bands of the signal is desired to be processed in accordance with the present invention. For example, a frequency band encompassing facsimile tone frequencies may be a sole band in which the processing of the present invention is applied in a multi-band processing scheme.

Embodiments of the present invention may be applied in conjunction with the ADRO technique set out in U.S. Pat. No. 6,731,767. However, embodiments of the present invention may be applied in conjunction with any sound processing technique in which a signal is processed to be matched to a parameter-defined target dynamic range.

It is to be appreciated that the phrase “sound signal” is used herein to refer to any signal conveying or storing sound information, and includes an electrical, optical, electromagnetic or digitally encoded signal.

### BRIEF DESCRIPTION OF THE DRAWINGS

Examples of the invention will now be described with reference to the accompanying drawings in which:

FIG. 1 illustrates input/output functions for linear amplification and for compression amplification schemes;

FIGS. 2A to 2D are block diagrams illustrating the use of a monitored signal condition to adaptively vary at least one signal processing parameter of an ADRO signal processing scheme in accordance with first to fourth embodiments of the present invention;

FIGS. 3a and 3b are schematics of a sound processing scheme in a duplex system in which a monitored signal condition of a line out influences signal processing parameters of the line in, in accordance with a fifth embodiment of the present invention;

FIG. 4 is a schematic of an environmental noise estimator suitable for use in the fifth embodiment of FIG. 3;

FIG. 5 is a schematic of a signal activity detector suitable for use in the fifth embodiment of FIG. 3;

FIGS. 6a and 6b are graphs of the magnitude of a difference between an upper end and a lower end of a target dynamic range for varying signal to noise ratio (SNR), in bands centred at 250 Hz and 1 kHz respectively, suitable for use as look-up tables to determine signal activity in the first to fourth embodiments of FIGS. 2A to 2D or the fifth embodiment of FIG. 3;

FIG. 7 illustrates the frequency response of a differentiator filter for removing low frequency components not relevant to noise estimation in the first to fourth embodiments of FIGS. 2A to 2D or the fifth embodiment of FIG. 3;

FIG. 8a illustrates variation of target dynamic range parameters with varying ambient noise in accordance with the fifth embodiment of FIG. 3;

FIG. 8b illustrates the variation of sound level resulting from the parameter variation of FIG. 8a;

FIG. 8c illustrates variation of the signal to noise ratio resulting from the parameter variation of FIG. 8a;

FIG. 8d illustrates the improved intelligibility resulting from the parameter variation of FIG. 8a;

FIG. 8e illustrates variation of perceived loudness of the output signal in the presence of ambient noise resulting from the parameter variation of FIG. 8a;

FIG. 9 illustrates frequency dependent variation of parameters in response to an increase in ambient noise in accordance with the fifth embodiment of FIG. 3;

FIG. 10 illustrates frequency spread of masking for narrowband noise with increasing noise level;

FIG. 11 illustrates the average spectral magnitudes of Hoth shaped noise;

FIG. 12 illustrates variation of gain slew rate with a measure of increasing mismatch between output dynamic range and target dynamic range;

FIG. 13a is a spectrogram of a sound signal processed by ADRO with fixed gain slew rate in which an alarm commences and then halts;

FIG. 13b is a spectrogram of a sound signal processed by ADRO with adaptive gain slew rate in which an alarm commences and then halts;

FIG. 13c is a plot of gain vs. time for a particular frequency band containing alarm frequency components for both the fixed gain slew rate of FIG. 12a and the adaptive gain slew rate of FIG. 13b; and

FIG. 14 is a schematic of a sound processing scheme where the monitored signal condition of a line in is used to adapt ADRO parameters for the purposes of protecting the listener from acoustic startle or shock signals, in accordance with a sixth embodiment of the present invention.

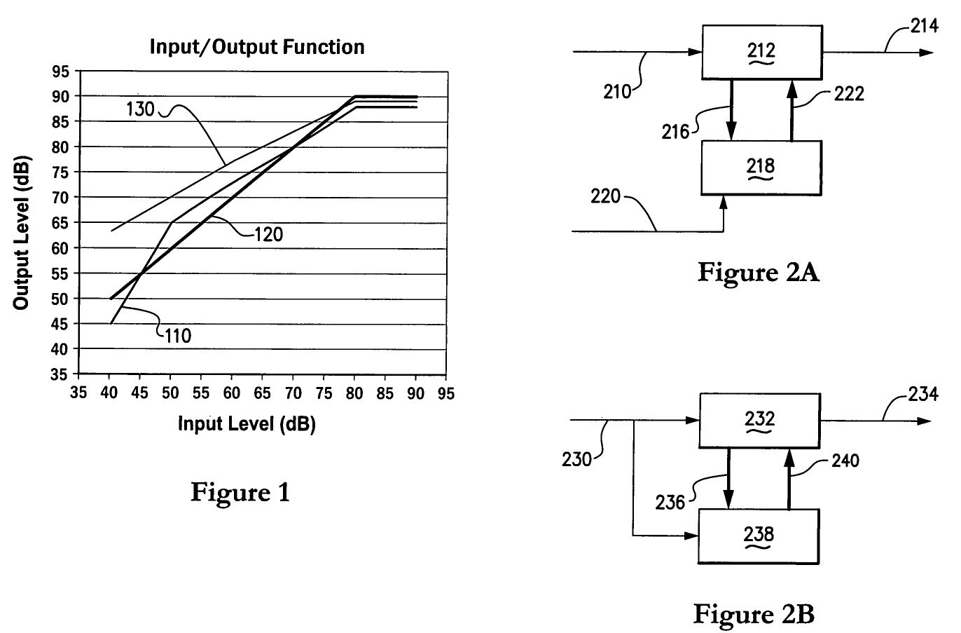

### DETAILED DESCRIPTION OF THE PREFERRED EMBODIMENTS

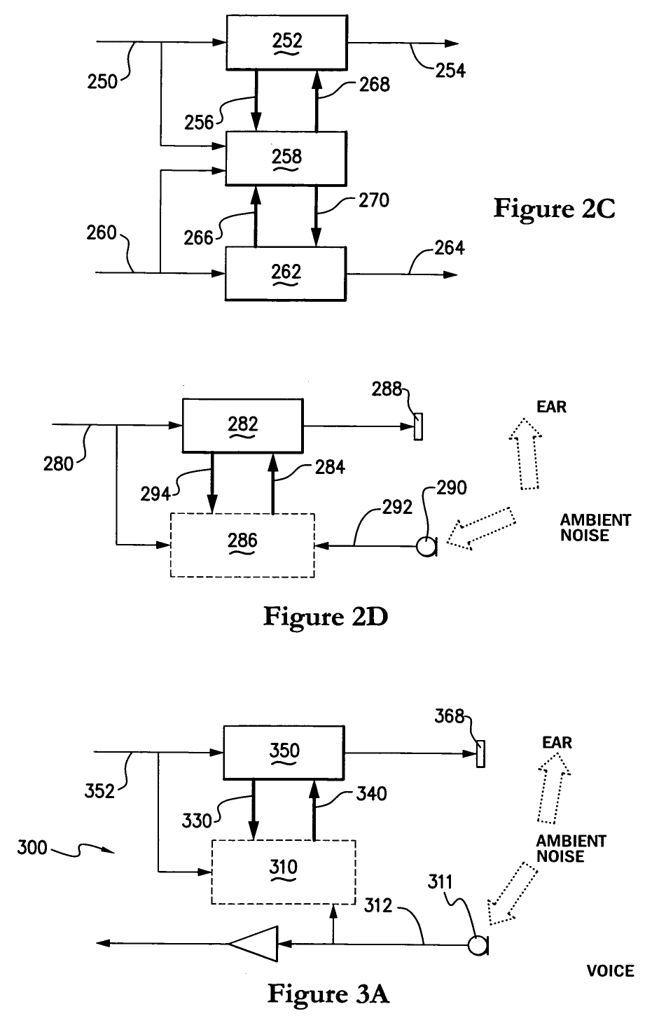

FIG. 2A is a block diagram illustrating the use of a monitored signal condition to adaptively vary at least one signal processing parameter of an ADRO signal processing scheme in accordance with a first embodiment of the present invention. Input sound signal 210 is conditioned by an ADRO processor 212 to generate a processed sound signal 214. ADRO processor 212 obtains statistics from processed sound signal 214 and at 216 passes those statistics to an adaptive parameters processor 218. Adaptive parameters processor 218 further monitors a signal condition of a second input signal 220, and adapts processing parameters accordingly, which at 222 are passed to the ADRO processor 212.

FIG. 2B is a block diagram illustrating the use of a monitored signal condition to adaptively vary at least one signal processing parameter of an ADRO signal processing scheme in accordance with a second embodiment of the present invention. Input sound signal 230 is conditioned by an ADRO processor 232 to generate a processed sound signal 234. ADRO processor 232 obtains statistics from processed sound signal 234 and at 236 passes those statistics to an adaptive parameters processor 238. Adaptive parameters processor 238 further monitors a signal condition of input signal 230, and adapts processing parameters accordingly, which at 240 are passed to the ADRO processor 232.

FIG. 2C is a block diagram illustrating the use of a monitored signal condition to adaptively vary at least one signal processing parameter of an ADRO signal processing scheme in accordance with a third embodiment of the present invention. A first input sound signal 250 is conditioned by a first ADRO processor 252 to generate a first processed sound signal 254. First ADRO processor 252 obtains statistics from first processed sound signal 254 and at 256 passes those statistics to an adaptive parameters processor 258. A second input sound signal 260 is conditioned by a second ADRO processor 262 to generate a second processed sound signal 264. Second ADRO processor 262 obtains statistics from second processed sound signal 264 and at 266 passes those statistics to adaptive parameters processor 258. Adaptive parameters processor 258 monitors at least one signal condition of each of input signals 250 and 260, and adapts processing parameters for each ADRO processor 252, 262 accordingly. Thus, the adaptive parameters of both ADRO processors 252, 262 may be influenced by monitored signal conditions of either or both input signals 250, 260. At 268, 270, adapted processing parameters are passed to the ADRO processors 252, 262, respectively.

FIG. 2D is a block diagram illustrating the use of a monitored signal condition to adaptively vary at least one signal processing parameter of an ADRO signal processing scheme in accordance with a fourth embodiment of the invention. In this embodiment, a line input signal 280 is conditioned by an ADRO processor 282. The ADRO processor 282 functions in accordance with processing rules controlled by adaptive parameters 284, the adaptive parameters 284 being altered as necessary by adaptive parameter processor 286. The input signal 280 is processed by the ADRO processor 282 to produce an acoustic output at the earpiece 288 for a listener using a headset or telephone handset.

The adaptive parameter processor 286 takes inputs both from the line input 280 and from a secondary source such as an ambient noise microphone 290. For example, in a duplex system the ambient noise microphone signal 292 may be from a headset or handset voice microphone used to obtain a voice signal from the listener. Alternatively the ambient noise microphone signal 292 may be from another microphone measuring the acoustic environment in the proximity of the listener. The adaptive parameters processor 286 can also use statistics such as output percentile estimates 294 from the ADRO processor 282.

In the fourth embodiment of FIG. 2D, the adaptive parameter processor 286 adapts comfort and audibility targets in each band in response to an estimate of the environmental noise obtained from the microphone signal 292. The adaptive parameter processor 286 further adapts the ADRO gain slew rate by band, and further adapts a maximum output limit parameter in response to properties of the line input signal 280.

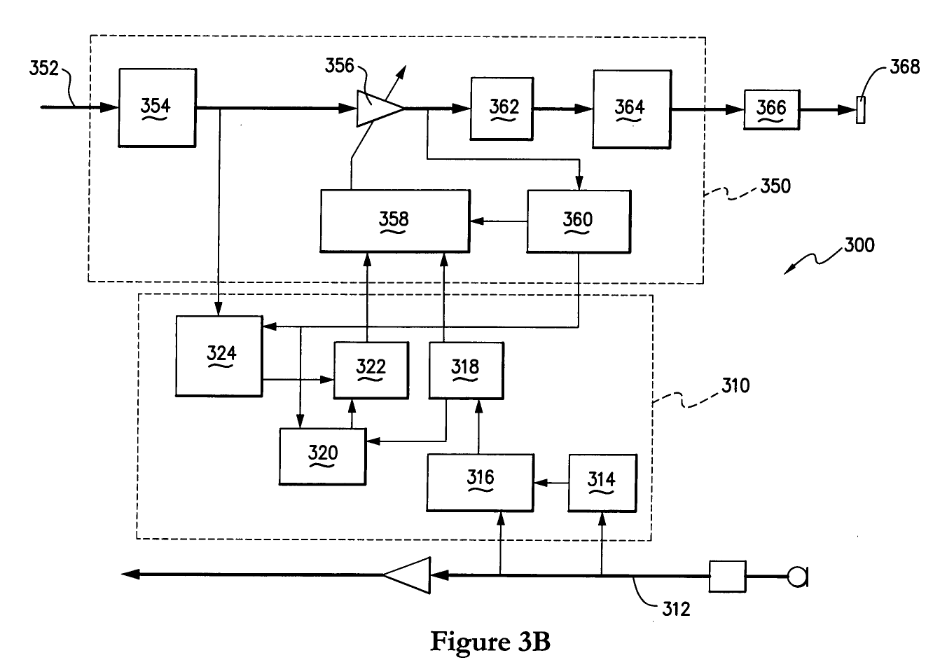

FIG. 3A is a simple block diagram of a fifth embodiment of the present invention, in which sound processing apparatus 300 is for use in a duplex sound signal system. An input line signal 352 is processed by ADRO processor 350 to produce a processed sound signal for speaker 368. Ambient noise in the vicinity of earpiece 368 is detected by microphone 311, which may also be used to detect voice signals. Adaptive parameters processor 310 monitors a signal 312 from microphone 311, input line signal 352, and statistics such as output percentile estimators passed at 330 from ADRO processor 350. From such inputs, the adaptive parameters processor adapts processing parameters which are passed at 340 to the ADRO processor 350.

FIG. 3B is a more detailed schematic of the fifth embodiment of the present invention. ADRO processor 350 takes a line in signal 352 which is processed by a filter bank analyser 354 and divided into multiple band signals corresponding to multiple frequency bands. In the present embodiment parameters applicable to every band of the input line signal 352 as extracted by the filter bank analyser 354 are adaptive. A variable gain is applied by amplifier 356 to match an output dynamic range to a target dynamic range. The variable gain is controlled by variable gain controller 358. A percentile estimator 360 obtains percentile estimates of an output signal of amplifier 356, to assist variable gain controller 358 in gain control. A volume controller 362 applies a volume parameter and a maximum output level parameter to the output signal of amplifier 362, after which a filter bank synthesiser 364 synthesises each processed band signal. A digital to analog converter (DAC) 366 converts the synthesized signal for a speaker 368.

An adaptive parameter processor 310 monitors a signal condition of microphone signal 312, and influences signal processing parameters applied by ADRO processor 350 to the line in signal 352. Adaptive parameter processor 310 comprises a signal activity detector 314 which monitors microphone signal 312 to determine whether a signal of interest is present on microphone signal 312, or whether ambient noise is the only signal present on microphone signal 312.

Adaptive parameter processor 310 further comprises an environmental noise estimator-316. Should signal activity detector 314 indicate that a signal of interest is present on microphone signal 312, operation of environmental noise estimator 316 may be paused to ensure that ambient noise measurements are not corrupted by non-noise signals. Environmental noise estimator 316 monitors microphone signal 312 in order to determine properties of the environmental noise in a listener's vicinity. Such properties can include estimates of ambient or environmental noise level, noise dynamic range, noise modulation or other properties useful for adapting the ADRO target levels. Such properties may be determined for the noise signal as a whole, or for noise signal sub-components determined by a frequency or transform domain filter-bank (not shown).

Adaptive parameter processor 310 further comprises an adaptive targets processor 318, which adapts dynamic range target parameters such as comfort and audibility targets in each band in response to an estimate of the environmental noise produced by environmental noise estimator 316. An output error estimator 320 determines an output error by measuring a mismatch between the output dynamic range defined by percentile estimates obtained by percentile estimator 360 and a target dynamic range defined by adaptive targets which are controlled by adaptive targets processor 318.

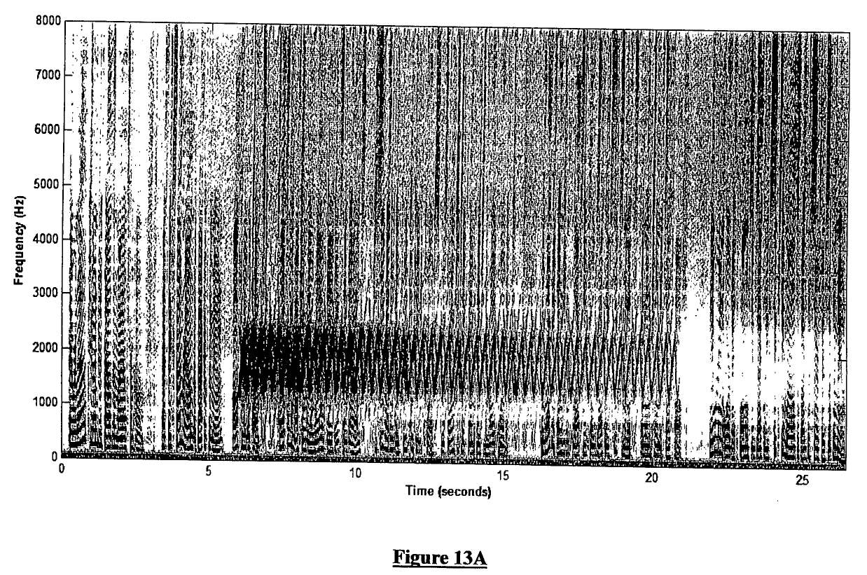

An adaptive rate processor 322 controls slew rates of variable gain controller 358, in particular a gain slew rate and a percentile estimate slew rate. As discussed inn more detail with reference to FIG. 11, the gain slew rate imposed by adaptive rate processor 322 is controlled to be at most 3 dB/s, unless the output error or mismatch determined by output error estimator is above a threshold error level. For output errors or mismatches above the threshold error level, the gain slew rate is permitted to become correspondingly larger.

A filter signal activity detector 324 monitors the output of filter bank analyser 354 and, with reference to the current percentile estimates obtained by percentile estimator 360, assesses whether a signal-of-interest is present, or whether only noise is present. Such an assessment may then be used to influence the adaptive gain and/or the adaptive gain slew rate. For example, during a period in which filter signal activity detector 324 determines that no signal-of-interest is present, adaptive rate processor 322 may prevent any increase in gain. Such control may prevent processor gain increasing during a pause in input signal, only for the gain to have become excessive by the time the input signal resumes.

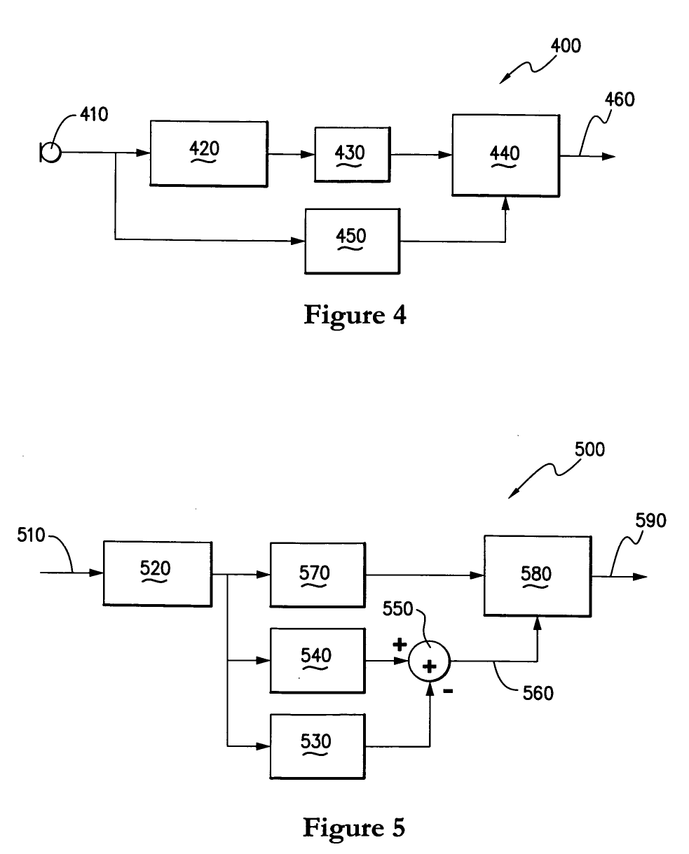

FIG. 4 is a schematic of an environmental noise estimator 400 suitable for use as environmental noise estimator 316 in the sound processing apparatus 300 of FIG. 3. A microphone 410 obtains a signal which is filtered by a set of calibration and weighting filters 420, before a power calculation of |x|², applied by power calculator 430. The result of this power calculation is used as the input into a weighted leaky integrator 440 that averages the power level over a specified time period. A signal activity detector 450 is used to provide activity information regarding the microphone signal that controls the leaky integrator 440 in each time period. The result of the process is an estimate 460 of environmental noise power. Use of signal activity detector 450 enables microphone 410 to also be used to measure another signal such as speech from a headset wearer. Signal activity detector 450 discriminates between a microphone signal that represents a true measurement of background noise versus a signal that is biased by the wearer's speech or other non-noise components. This discrimination can be performed for individual frequency sub-bands of the signal, the full band of the signal, or both individual frequency sub-bands and the full band using a system that combines the discrimination results.

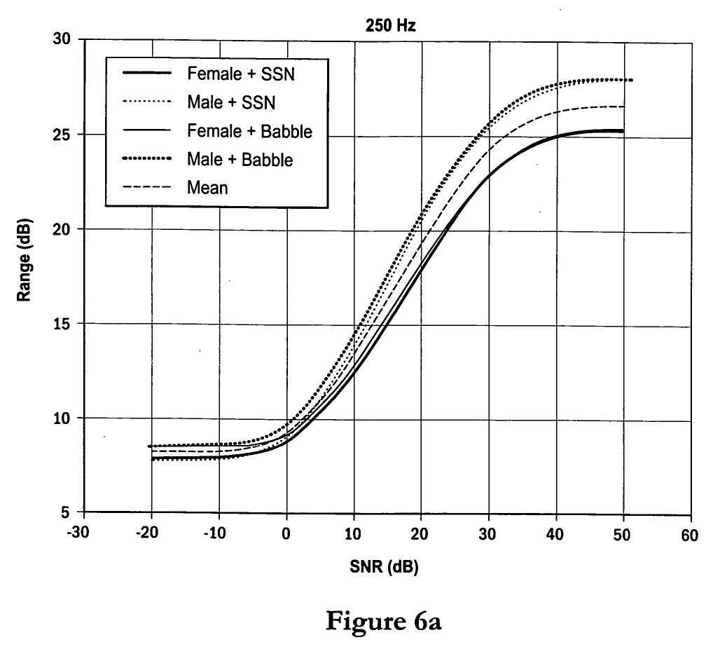

FIG. 5 is a schematic of a signal activity detector 500 suitable for use as signal activity detector 314 in the sound processing apparatus 300 of FIG. 3, and signal activity detector 450 in the environmental noise estimator 400 of FIG. 4. The signal activity detector 500 takes an input signal 510 and magnitude estimator 520 determines the |x| magnitude of the input signal 510. The outputs of a 10^{th} percentile estimator 530 and a 90^{th} percentile estimator 540, similar to those used in ADRO itself are used to determine a level of modulation of the signal 510, by being summed at 550 to produce a modulation estimate 560.

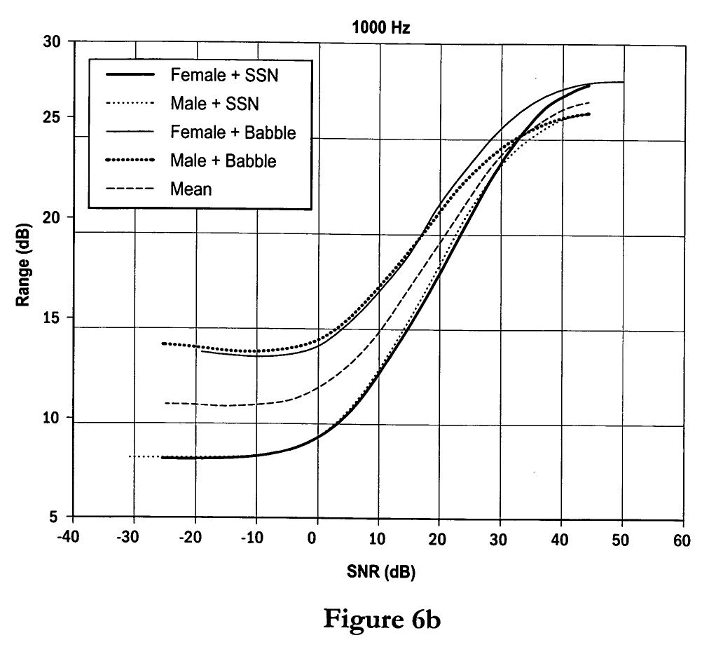

An activity estimator 580 uses an output of a 50^{th} percentile estimator 570 and the modulation estimate 560 to provide a signal activity level 590. The modulation criterion is based on a well defined relationship between speech to noise ratio (SNR) and modulation levels as measured by the percentile estimate difference. For example, FIGS. 6a and 6b are graphs of the average magnitude of a difference between an upper end and a lower end of a target dynamic range for varying signal to noise ratio (SNR), in bands centred at 250 Hz and 1 kHz respectively, suitable for use as look-up tables to determine signal activity. FIGS. 6a and 6b show the results of measurements of average percentile estimate difference as a modulation range (dB), with varying SNR (dB). These measurements were made for combinations of male and female speech with common noises such as babble and speech shaped noise (SSN), in 250 Hz wide frequency sub-bands centred at 250 Hz and 1000 Hz. This type of information is combined with overall signal level information represented by the 50^{th} percentile measurement, to make a determination of the SNR or ambient noise activity of the microphone signal 510. Other implementations for signal activity detection may alternatively be used.

The output 590 of a signal activity detector 500, when implemented as signal activity detector 314 in the sound processing apparatus 300 of FIG. 3, is used to control the updating of the environmental noise estimator 316 so that the noise property estimates made by environmental noise estimator 316 are not biased by non-noise signals. The leaky integrator 440 which outputs the final noise level estimate of environmental noise estimator 400/316 is only updated when the signal activity detector 500/314 indicates that no signal-of-interest or wearer speech signal is present in the measured microphone signal 312/410. Alternatively, the leaky integrator 440 may only be updated by an amount that is weighted by the signal activity level provided by the signal activity detector 500/314.

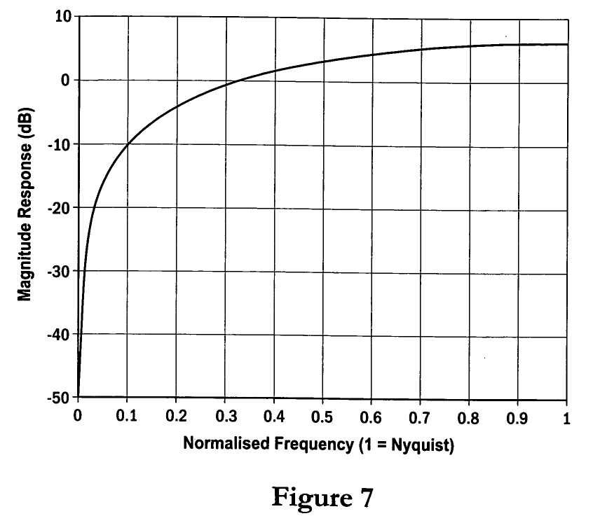

The calibration and weighting filters 420 initially applied to the microphone signal 410 measured for environmental noise estimation purposes is used to alter the spectral content of the signal to make it more suitable for processing, and/or to compensate and calibrate for microphone properties. For example, a filter with an ‘A’ weighting response can be used to emphasise those frequencies in the signal that are perceived more loudly by normal hearing listeners. In another example, a differentiator filter (y[n]=x[n]−x[n−1]) can be used to produce a high pass response, and thereby remove low frequency noise and transients commonly present in the microphone signal but not relevant for the noise estimate performed by environmental noise estimator 400/316. FIG. 7 illustrates the frequency response of a differentiator filter for removing low frequency components not relevant to noise estimation.

The output of environmental noise estimator 316 is used by the adaptive target processor 318 to adapt the ADRO target dynamic range, particularly by varying the comfort target, audibility target and maximum output limit parameters. The primary objectives of such parameter variations are to maintain the intelligibility, audibility and comfort of the received signal, despite significant noise level variation. This parameter variation can be based on a simple linear or non-linear relationship between noise and target levels, or a more complex relationship that takes into account priorities for comfort, audibility and/or intelligibility depending on application and/or personal preference.

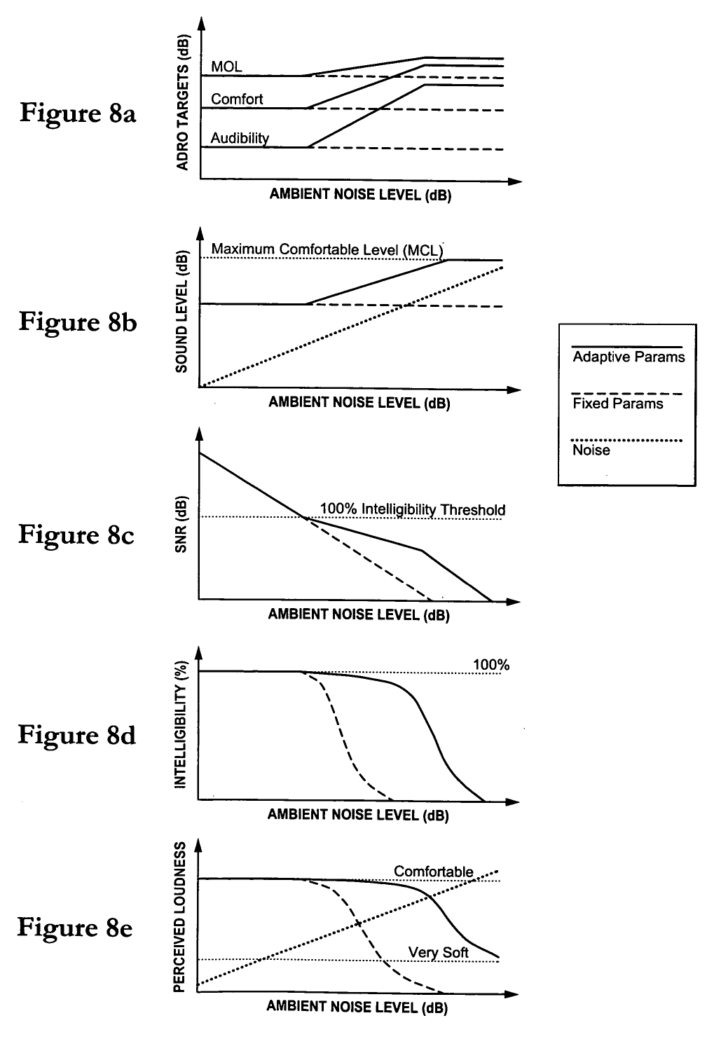

FIG. 8 compares some properties of a fixed parameters version of ADRO, and a simple adaptive parameters version in accordance with the present invention. FIG. 8a illustrates variation of target dynamic range parameters with varying ambient noise. Adaptive parameters include the maximum output level (MOL), comfort target and audibility target in each band. Below an ambient noise threshold, the target dynamic range parameters are maintained constant in accordance with known ADRO processing techniques. However, as ambient noise increases above the threshold, the target dynamic range parameters are increased, in such a manner that the difference between the comfort target and audibility target parameters decrease.

An increase in MOL and comfort level will usually be acceptable due to the increased ability of the listener to handle loud noise in the presence of substantial ambient noise. An increase in the audibility target parameter maintains the target dynamic range above the ambient noise, even as the ambient noise increases. Above a second threshold, further increases in the target dynamic range parameters are not permitted even with further increases in ambient noise, to prevent hearing damage to the listener by the output sound signal.

FIG. 8b illustrates the variation of sound level resulting from the parameter variation of FIG. 8a. FIG. 8c illustrates variation of the SNR resulting from the parameter variation of FIG. 8a. SNR is important for intelligibility, and it is notable in FIG. 8c that providing adaptive parameters in accordance with the present invention maintains a higher SNR for a larger portion of the ambient noise range. FIG. 8d illustrates the improved intelligibility resulting from such parameter variation, and FIG. 8e illustrates variation of perceived output loudness with ambient noise resulting from the parameter variation of FIG. 8a. Notably, FIG. 8e shows that the adaptive parameters maintain the output signal to be both audible and at a comfortable level for a larger portion of the ambient noise range.

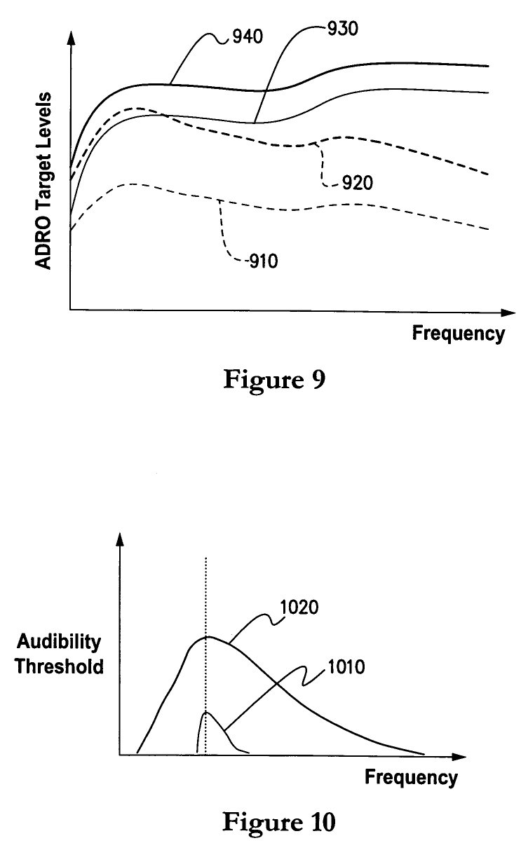

The variation of parameters can be made in common across all ADRO processing channels, or made independently so that the parameter adaptation is customised to each frequency band or filter-bank channels. Further, parameter adaptation can be customised to each frequency band in response to band-specific properties such as a noise level or noise property estimate in the frequency band or filter-bank sub-band. Such band-specific parameter adaptation may cause the target dynamic range variation in one ADRO band to respond to the noise properties at common masking frequencies more than to the noise at other frequencies. FIG. 9 illustrates frequency dependent variation of parameters in response to an increase in ambient noise.

FIG. 9 shows plots of initial audibility targets 910 and initial comfort level targets 920, across all frequency bands of the ADRO processor. Such initial targets may be applied in response to an initial low ambient noise level. In response to an increased ambient noise level, the audibility target and comfort level target of each frequency band may be adapted, in a variable manner from one frequency band to the next, to produce the plots of updated audibility targets 930 and updated comfort level targets 940. In this case, in response to an increase in the environmental noise level, the targets are increased to a greater extent at high frequencies compared to low frequencies.

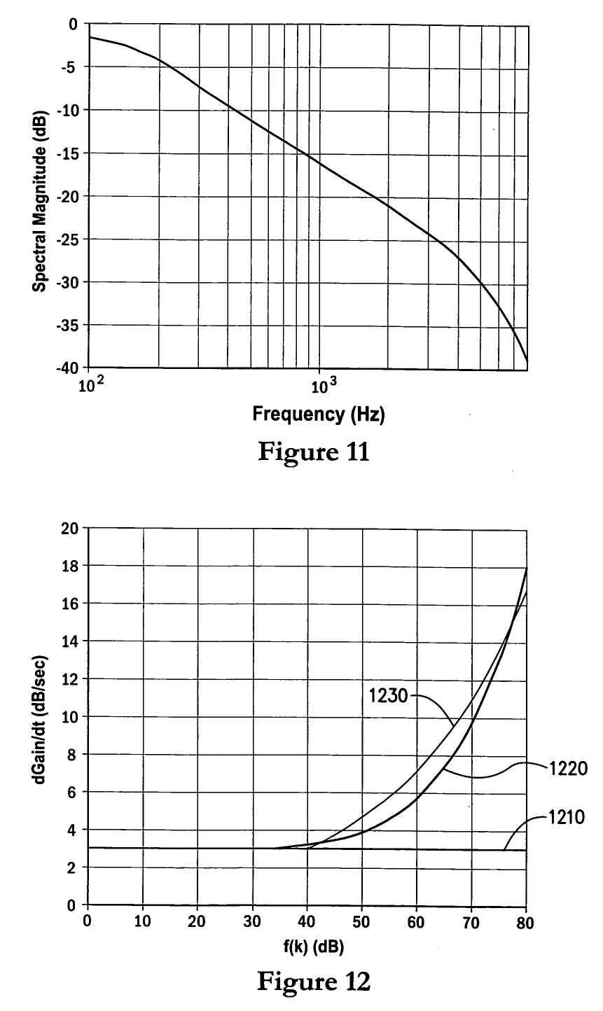

Such a variation with frequency recognises the upward spread of masking, a phenomenon in psychoacoustics which suggests that the threshold for audibility of hearing at one frequency is conditioned by the presence of interfering noise components at lower frequencies more than at higher frequencies. That is, a noise component will tend to mask signals occurring at and above the masking frequency, more than at and below the masking frequency. FIG. 10 shows a typical pattern of threshold change across frequency for a low level 1010 of narrowband masking noise, and a higher level 1020 of narrowband masking noise. Since low frequency noise tends to mask audibility at higher frequencies, more significant benefits can be obtained by increasing high frequency signal components compared to low frequency.

The frequency variable adaptation of parameters shown in FIG. 9 is further based on the typical Hoth spectrum of ambient noise. The Hoth spectrum of noise is illustrated in FIG. 11, and represents a typical spectrum of ambient noise, and is defined in IEEE 269-2002, Standard Methods for Measuring Transmission Performance of Analog and Digital Telephone Sets, Handsets, and Headsets. The Hoth spectrum has a different frequency emphasis compared to speech, and therefore improved intelligibility in such environments is obtained by customising the adaptation to ambient noise across frequency in a way that exploits this unique spectral characteristic.

The frequency variable adaptation of parameters shown in FIG. 9 further recognises the tonal properties of raised speech. When a voice is raised in natural face-to-face speech, for example in response to an increase in ambient noise, the speaker will typically talk such that the high frequencies are slightly more emphasised over speech at a normal level. By reproducing this effect in the adjustment of the targets, a more natural sound for the signal can be obtained when the environmental noise level is high.

Still further, the frequency variable adaptation of parameters shown in FIG. 9 recognises typical receiver response capabilities. When the level of the sound output from a receiver or speaker is increased, the output can often distort or reach a hardware limit more quickly in the low frequencies than in the high frequencies. By increasing low frequencies more slowly than high frequencies, intelligibility and sound quality can be maintained for more of the ambient noise level range than if targets at all frequencies were increased in the same way.

Again, in each frequency band a difference between the comfort level target 940 and the audibility target 930 (high ambient noise), is less than a difference between the comfort level target 920 and the audibility level target 910 (low ambient noise). In general, the response to higher levels of ambient noise can be improved by reducing the target dynamic range and/or compressing the input dynamic range. Additional audibility can be obtained without exceeding comfort limits by compressing the signal or raising the audibility target towards an upper limit such as the comfort target. This is particularly useful at higher frequencies (above 2 kHz), where output levels are closer to comfort or maximum output limits, and where significant information for speech intelligibility in noise is still contained.

When the audibility target is raised towards the comfort target, the ADRO processor will more often increase gain in soft periods of the signal where the comfort target is not active, such that in these periods there is improved audibility over the background noise. With this arrangement, the signal dynamic range is minimally compressed or distorted over the short term, but has improved audibility without violating comfort targets over the longer term.

Alternatively or additionally, the dynamic range of the signal can be directly compressed before application of the ADRO processor rules, based on for example the proximity of the lower end of the signal dynamic range to the middle or upper end of the noise dynamic range. This allows the time constant and ratio of any compression effect to be set independently of the ADRO processor rules, but causes higher distortion due to the increased rates of gain change commonly used with compression systems. This process is therefore most useful only when the audibility of the signal is more important than sound quality of the signal, as can be the case when the ambient noise level is particularly high.

Further, it is noted that adaptive rate processor 322 provides for adaptive control over gain slew rate in response to a monitored signal condition. The present invention recognizes that existing implementations of ADRO adapt gain levels at a constant slew rate, typically 3 dB per second. This rate is constant under all circumstances, regardless of the magnitude of change or rate of change in the input audio conditions. While this helps to ensure less distortion and ‘pumping’ of the gain levels in response to small input changes typical in speech, the present invention recognises that such a low constant slew rate causes a slower response than may be required when the changes in input signal are more significant. Thus, adaptive rate processor 322 may be configured to provide for a more rapid gain slew rate in response to sudden large input signal changes. For example, adaptive rate processor 322 may be configured to provide for a more rapid gain slew rate at hearing aid turn-on, such as the initial response to a particularly quiet or loud audio environment Further, adaptive rate processor 322 may be configured to provide for a more rapid gain slew rate during or after testing, in which an extended high output may otherwise result after maximised gain due to very quiet initial ambient testing levels. Further, adaptive rate processor 322 may be configured to provide for a more rapid gain slew rate to suppress a source of acoustic startle such as an alarm or facsimile tone.

In implementing the adaptive rate processor 322, the present invention applies the following design principles: avoiding unnecessary increases in slew rate, particularly during normal conditions in speech or music; avoiding slew rates so high that they virtually remove or unduly reduce a cue for a change in levels; and avoiding slew rates faster than a ‘slow time constant’ rate (e.g. up to 20 dB/sec) for reasons of sound quality and numerical stability.

In one embodiment, the adaptive rate processor may comprise a non-linear function or look-up table using a measure of ‘distance’ of the current output dynamic range to the target dynamic range, to determine an adjustment to the slew rate. The non-linear function is very small or 0 for relatively small distances (eg during speech or music), but becomes larger when conditions have changed more strongly and the distance is more significant. Some examples of modelled analytical functions for gain slew rate that include such a non-linear term are given below:

$$\vert \frac{δ {Gain}_{k}}{δ t} \vert = 3 + K \cdot {\vert f ( k ) \vert}^{q} ( dB / sec )$$

$$\vert \frac{δ {Gain}_{k}}{δ t} \vert = 3 \cdot {2}^{max ( 0 , K . \vert f ( k ) \vert - M )} ( dB / sec )$$

In these equations, k is an index identifying the signal or part of a signal being controlled, |f(k)| is the ‘distance’ metric, and K, q and M are constants that shape and position the non-linear response. A minimum gain slew rate of 3 dB/sec is assumed in these particular equations, however the gain slew rate could be made slower than 3 dB/s. A slower slew rate when the distance is very small could improve sound quality slightly by ensuring the gain is more stable when the input signal level is at an equilibrium.

Sample ‘distance’ metrics which may be applied to determine a magnitude of a mismatch between an output signal dynamic range and a target dynamic range include a measure of difference between the dynamic range targets and the percentile estimates, as these are the pre-existing parameters in the system. For example:
f(Pₖ,Tₖ)=T_{Comfort,k}−P_{90,k}
f(Pₖ,Tₖ)=T_{Audibility,k}−P_{30,k}
f(Pₖ,Tₖ)=(T_{Comfort,k}+T_{Audibility,k})−(R_{90,k}+P_{30,k})
f(Pₖ,Tₖ)=(T_{Comfort,k}+T_{Audibility,k})/2−P_{50,k}
f(Pₖ,Tₖ)=(2·T_{Comfort,k}−25)−(P_{90,k}+P_{30,k})

where Pₖ and Tₖ are the sets of percentile estimates and targets for the k^{th} signal or part of a signal, respectively.

The temporal behaviour of these distance metrics is dictated by the relative step rates of the percentile estimate. Hence the first two metrics tend to cause asymmetric responses, resulting in faster slew rates to change gain in one direction (up or down) than the other. The third and fourth metrics average these results to produce a more symmetric slew rate response. The final metric above replaces the audibility target with a ‘comfortable speech 30th percentile target’: T_{comfort}-25, to provide a balanced response, with less bias when at equilibrium.

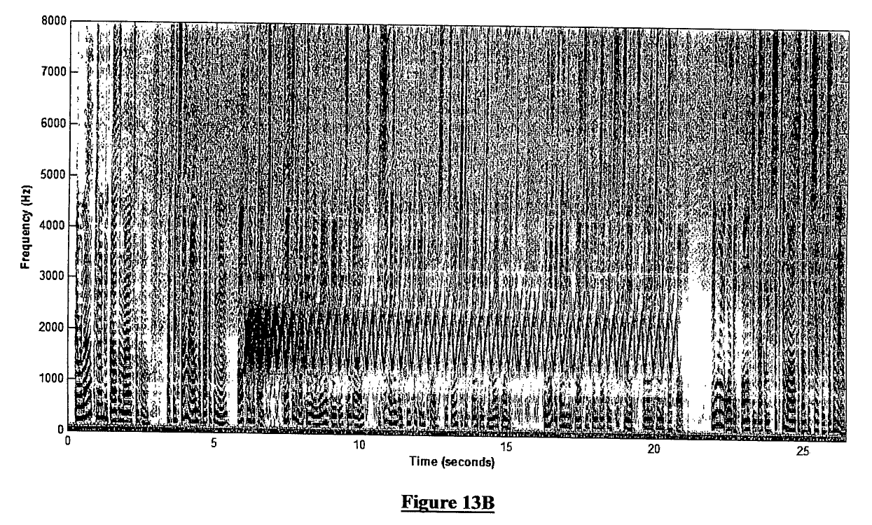

FIG. 12 illustrates variation of gain slew rate with increasing mismatch. 1210 is a fixed gain slew rate in response to an increasing mismatch, while 1220 and 1230 are two non-linear functions for determining an adjustment to gain slew rate. In practice it is useful to limit the maximum slew rate at any time to avoid problems associated with over-shoot and numerical stability in the adaptive rates processor.

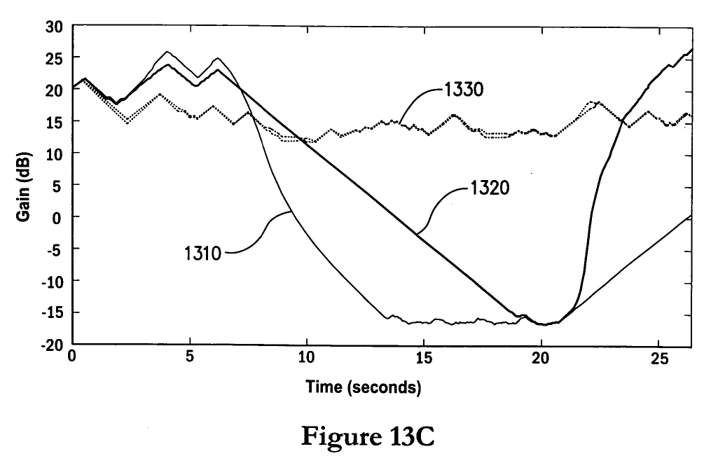

FIG. 13A is a spectrogram of a sound signal processed by ADRO with fixed gain slew rate in which an alarm centered at about 2 kHz commences at about 6.5 seconds and then halts at about 21 seconds. FIG. 13B is a spectrogram of the same sound signal when processed by ADRO with adaptive gain slew rate. FIG. 13C is a plot of gain vs. time, illustrating gain variation during the signals of FIGS. 13A and 13B, for the gain in the 2 kHz frequency region. 1310 is a plot of gain at the alarm frequency under the adaptive slew rate applied in accordance with the present invention, while 1320 is a plot of gain at the alarm frequency under a fixed gain slew rate technique. 1330 is a plot of gain at frequencies away from the alarm, for both the adaptive and fixed slew rate techniques.

Notably, following commencement of the alarm, the fixed slew rate gain plot 1320 decreases only at the allowed fixed rate of 3 dB/s. Consequently, during the period 6.5 seconds to about 20 seconds, the fixed slew rate system of FIG. 13A and plot 1320 allows the alarm to pass through the processor at higher than desired levels. To the contrary, the adaptive slew rate gain plot 1310 decreases at a variable rate, corresponding to the mismatch between the output dynamic range and a target dynamic range. From about 6.5 seconds to about 11 seconds the gain plot 1310 decreases at a variable rate, of greater than 3 dB/s. From about 11 seconds to about 13 seconds the gain plot 1310 decreases at 3 dB/s. Gain plot 1310 shows that a variable slew rate technique thus suppresses such sudden input signal variations substantially more rapidly than a fixed slew rate technique. Further it is notable from the plots 1330 in FIG. 13c that the fixed slew rate technique and the adaptive slew rate technique act substantially the same during periods or at frequencies where there is little or no input signal change.

Thus, in a sound environment of a listener with normal hearing listening to a telephone signal transmitted by a telephone line or a mobile telephone, the present invention recognizes that the audibility of the signal will depend on the masking effect of the ambient noise in the listener's noise environment. Accordingly, in the present embodiment the ambient noise of the listener's noise environment is monitored and used as a monitored signal condition for adaptively varying at least one band-specific parameter. The masking effects of such ambient noise may depend on the type of noise and on the level of the noise. One, some or all of the ADRO parameters (including maximum output limit, comfort target, audibility target, maximum gain and gain slew rate, for each band) may be made adaptable to maintain the signal at an audible level relative to the listener's ambient noise conditions, while still maintaining the comfort of the listener. As such parameters are varied over time in response to the ambient noise, the normal adaptive function of ADRO will simultaneously compensate for changes in the input signal to fit the output dynamic range to the target dynamic range, in accordance with the rules specified by the adaptive band-specific parameter(s).

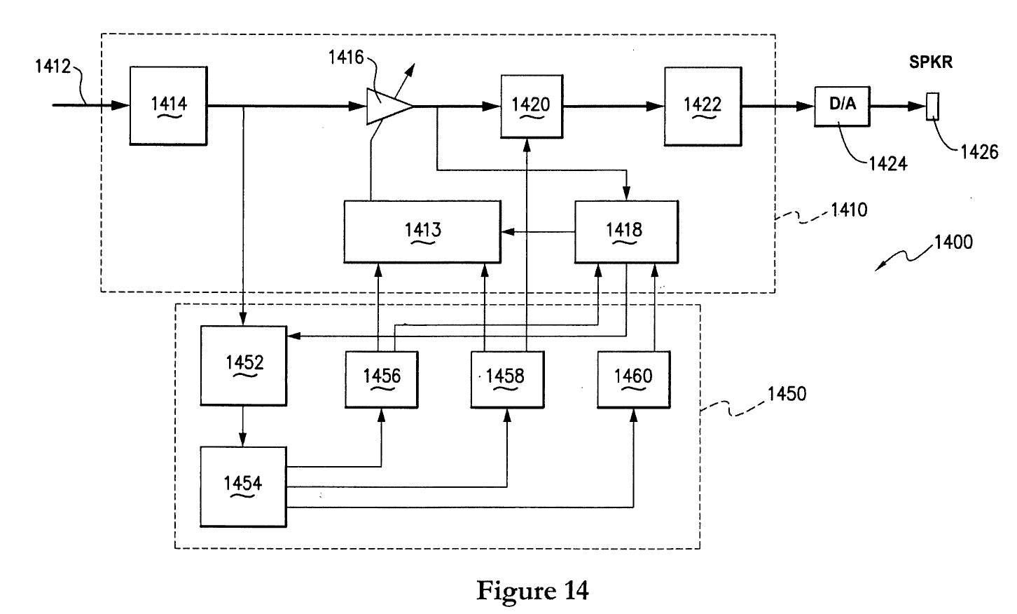

FIG. 14 is a schematic of a sound processing apparatus 1400 intended for the detection of acoustic shock or startle signals present in an input sound signal 1412, for the purposes of adapting ADRO parameters to suppress such shock or startle signals, in accordance with a sixth embodiment of the invention. In FIG. 14, the input signal 1412 is passed through a filter bank 1414 and monitored by startle/shock detector 1452 to make a determination regarding the presence and location of high level signal components with characteristics strongly different to that of normal speech, and typical of shock signals such as fax tones, overly loud speech, feedback shrieks, or narrowband noise.

The detection of acoustic shock or startle frequency components in the presence of speech can be based on a number of criteria, including:

1. Signal level. Only those components with sufficiently high level are usually candidates for causing acoustic shock or startle symptoms. Acoustic shock or startle components often have a higher narrowband level than speech at the same frequency.

2. Modulation or dynamic range. Shock signals characteristically have lower modulation properties than that of speech, and this difference can be used to further discriminate between speech and non-speech components. Refer to the plots of average estimate range vs. signal to noise ratio in FIGS. 6a and 6b.

3. Spectral shape and peaks. The presence of narrowband shock or startle signals of sufficiently high level typically causes components of the frequency spectrum of the input signal to have one or several well defined peaks, with higher relative energy to the other components of the spectrum than is usually found in normal speech.

4. Rate of signal level change (attack or onset time). Acoustic shock or startle signals often commence very rapidly, causing a sudden increase in level of frequency components that is not typical of speech. This difference in onset time can be useful in making an early or initial determination regarding the presence of an acoustic shock signal, when other criteria such as the short term modulation are not yet indicative.

Once acoustic shock or startle components are determined to be present in the line input signal, the startle detector 1452 passes frequency location and other information to the shock or startle signal suppressor 1454. This suppression system controls the adaptation of ADRO parameters for the purposes of removal or attenuation of the shock or startle components by the ADRO processor. The suppression can be achieved by an adaptive ADRO slew rate adapter 1456, an adaptive ADRO target adapter 1458 and an adaptive ADRO state information adapter 1460 according to:
1. Adapting the relevant ADRO 90^{th} percentile estimates or percentile estimate slew rates so that the estimates are made to immediately represent the high level of the upper end of the dynamic range at the frequency regions of the shock or startle signal.
2. Adapting the downward gain slew rate to be increased so that the comfort target rule of the ADRO processor takes effect to quickly reduce gain at the frequency regions of the shock or startle signal, such that upper end of the dynamic range as represented by the 90^{th} percentile estimate is reduced below the comfort target.
3. Adapting the ADRO maximum output limit targets, implemented by ADRO volume control/MOL's 1420, to be reduced at the shock or startle frequencies so that there is a guarantee of reduced output levels, and no increase in levels for a specified time span.

With this arrangement the ADRO processor rapidly attenuates the acoustic shock signals to the level of the comfort target, and guarantees no increase of level at the acoustic shock frequencies for a sufficient time span to avoid the potential of shocks at similar frequencies in the near future.

Similarly to the sound processing apparatus 300 of FIG. 3, the sound processing apparatus 1400 further comprises an ADRO gain calculator 1413, an amplifier 1416, an ADRO percentile estimator 1418, a filter bank synthesizer 1422, a DAC 1424 and a speaker 1426.

It will be appreciated by persons skilled in the art that numerous variations and/or modifications may be made to the invention as shown in the specific embodiments without departing from the spirit or scope of the invention as broadly described. The present embodiments are, therefore, to be considered in all respects as illustrative and not restrictive.

1. A method of processing at least one input sound signal to meet a target dynamic range, the method comprising:
applying at least one input sound signal-specific gain to the at least one input sound signal to produce a processed sound signal;
measuring a dynamic range of the processed sound signal;
determining a match of the measured dynamic range with the target dynamic range; and
adjusting each input sound signal-specific gain in accordance with at least one input sound signal-specific parameter to improve the match of dynamic range of the processed sound signal to the target dynamic range, wherein the at least one input sound signal-specific parameter is adaptive in response to at least one monitored signal condition.

2. The method of claim 1, wherein the monitored signal condition comprises a measurement of a mismatch between the measured dynamic range and the target dynamic range.

3. The method of claim 2, wherein the at least one input sound signal-specific parameter comprises a gain slew rate of the gain adjustment.

4. The method of claim 3, comprising controlling the gain slew rate to be larger in magnitude when the mismatch is larger, and controlling the gain slew rate to be smaller in magnitude when the mismatch is smaller.

5. The method of claim 3, wherein the gain slew rate for an increase in gain is controlled to be different to the gain slew rate for a reduction in gain.

6. The method of claim 5, wherein the gain slew rate for the reduction in gain is permitted to be large, and wherein the gain slew rate for the increase in gain is limited to a moderate gain slew rate.

7. The method of claim 1, wherein the at least one monitored signal condition comprises an ambient noise signal condition.

8. The method of claim 7, wherein the ambient noise signal condition is monitored from at least one of: the at least one input sound signal; and at least one microphone in the environment of a listener of the processed sound signal.

9. The method of claim 7, wherein the at least one input sound signal-specific parameter comprises at least one of a target audibility level and a target comfort level, the method comprising increasing the at least one of the target audibility level and the target comfort level in response to an increase of the ambient noise signal condition.

10. The method of claim 7, wherein the at least one input sound signal comprises at least one low frequency band input sound signal and at least one high frequency band input sound signal, and wherein, in response to an increase of the ambient noise signal condition, the target dynamic range of the at least one high frequency band input sound signal is raised by an amount more than an amount by which the target dynamic range of the at least one low frequency band input sound signal is increased.

11. The method of claim 1, wherein the at least one monitored signal condition comprises the presence of a signal-of-interest, the method comprising monitoring an input signal in order to determine periods in which a signal-of-interest is present, and periods in which no signal-of-interest is present.

12. The method of claim 11, wherein the at least one input sound signal-specific parameter is a gain increase slew rate, and the method comprising setting the gain increase slew rate to zero during periods in which no signal-of-interest is present.

13. The method of claim 1, wherein the at least one monitored signal condition comprises the presence of audio shock.

14. The method of claim 13, wherein the at least one input sound signal-specific parameter comprises gain slew rate, and the method comprising imposing a large gain reduction slew rate for gain reduction in response to detection of presence of an audio shock.

15. The method of claim 13, wherein the at least one input sound signal-specific parameter comprises a maximum output limit, and the method comprising reducing the maximum output limit in response to detection of presence of an audio shock.

16. The method of claim 1, wherein the at least one adaptive input sound signal-specific parameter comprises at least one of: maximum output limit(s), comfort target(s), audibility target(s), background noise target(s), maximum gain(s), minimum gain(s), increasing gain slew rate(s), decreasing gain slew rate(s), increasing percentile estimate slew rate(s) and decreasing percentile estimate slew rate(s).

17. A device for processing at least one input sound signal to meet a target dynamic range, the device comprising:
a gain stage for applying at least one input sound signal-specific gain to the at least one input sound signal to produce a processed sound signal;
an analyser for measuring a dynamic range of the processed sound signal and for determining a match of the measured dynamic range with the target dynamic range; and
a gain controller for adjusting each input sound signal-specific gain in accordance with at least one input sound signal-specific parameter to improve the match of dynamic range of the processed sound signal to the target dynamic range, wherein the at least one input sound signal-specific parameter is adaptive in response to at least one monitored signal condition.

18. A computer program for processing at least one input sound signal to meet a target dynamic range, the computer program comprising:
code for applying at least one input sound signal-specific gain to the at least one input sound signal to produce a processed sound signal;
code for measuring a dynamic range of the processed sound signal;
code for determining a match of the measured dynamic range with the target dynamic range; and
code for adjusting each input sound signal-specific gain in accordance with at least one input sound signal-specific parameter to improve the match of dynamic range of the processed sound signal to the target dynamic range, wherein the at least one input sound signal-specific parameter is adaptive in response to at least one monitored signal condition.
